(19) United States
(12) Patent Application Publication
(10) Pub. No.: US 2023/0193913 A1
(43) Pub. Date: Jun. 22, 2023

(54) METHOD OF DETERMINING DELIVERY FLOW OR DELIVERY HEAD

(71) Applicant: Jens Olav FIEDLER, Dortmund (DE)

(72) Inventor: Jens Olav FIEDLER, Dortmund (DE)

(21) Appl. No.: 17/972,750

(22) Filed: Oct. 25, 2022

(30) Foreign Application Priority Data
Dec. 17, 2021 (LU) 501040

(51) Int. Cl. F04D 27/00; F04D 13/06

(52) U.S. Cl. CPC F04D 27/001; F04D 13/06

(57) ABSTRACT

A torque required to achieve the modulated reference speed or adjustment of a modulated torque and the actual speed of the centrifugal pump is determined. Then a model speed is calculated with the aid of a mathematical pump-motor model simulating the behavior of the centrifugal pump within a hydraulic system as well as a disturbance signal from a deviation of the model speed from the actual speed of the centrifugal pump. Then a correction signal is determined by integrating the product of the disturbance signal and a sine or cosine signal with a multiple of the excitation frequency over at least one period of the excitation signal. Finally, at least one model parameter of the pump-motor model is determined as a function of the correction signal and the flow rate and/or the head is calculated using the adapted pump-motor model.

### FIELD OF THE INVENTION

The invention relates to a method of determining the delivery flow and/or the delivery head of a speed-controlled centrifugal pump in a hydraulic pipeline network from a system response of the pipeline network detectable in the centrifugal pump to a periodic modulation of the speed and/or torque of the centrifugal pump.

Furthermore, the invention relates to a centrifugal pump comprising a centrifugal pump, an electric motor driving it and control electronics for controlling the electric motor with or without feedback and set up to carry out the method.

### BACKGROUND OF THE INVENTION

U.S. Pat. No. 10,184,476 describes how to stimulate a pipeline network by periodically modulating the setpoint speed or torque of a centrifugal pump in the pipeline network to provoke a system response that in turn is reflected in an evaluable response of the centrifugal pump, for example in the form of a change in the electrical power consumption or the torque required to maintain the (modulated) setpoint speed. The system response (magnitude, shape, phase, deceleration) depends on the so-called “hydraulic impedance” of the piping network. From the response of the centrifugal pump to this, it can determine its flow rate.

Investigations have shown that this method requires a comparatively large modulation amplitude to obtain a sufficiently high signal-to-noise ratio in the useful signal to be evaluated and thus enable reliable determining the volume flow and/or the delivery head. In contrast, the noise in the useful signal is comparatively high at a low modulation amplitude and thus worsens the accuracy of the volumetric flow determination. However, a large modulation amplitude leads to flow noise that is undesirable in pipe networks such as central heating systems or cooling systems.

### SUMMARY OF THE INVENTION

The object of the present invention is to improve the method known in the prior art, in particular to reduce the noise in the useful signal despite a comparatively low excitation amplitude and at the same time to increase the accuracy of the determining the flow rate.

### SUMMARY OF THE INVENTION

According to the invention, a periodic excitation signal of a certain excitation frequency is applied to a reference speed or torque of the centrifugal pump to obtain a modulated reference speed, and then to perform the following steps:
a. Determining and adjusting a torque required to achieve the modulated reference speed or adjusting the modulated torque,
b. Determining the actual speed of the pump,
c. Calculating a model speed with the aid of a mathematical pump-motor model simulating the behavior of the centrifugal pump within a hydraulic system,
d. Calculating at least one fault signal from a deviation of the model speed from the actual speed of the centrifugal pump,
e. Determining at least one correction signal by integrating the product of the disturbance signal and a sine or cosine signal with the single or a multiple of the excitation frequency over at least one period of the excitation signal,
f. Adaptation of at least one model parameter of the pump-motor model as a function of the correction signal, and
g. Calculating the flow rate and/or the head using the adapted pump-motor model.

Furthermore, a centrifugal pump with a centrifugal pump, an electric motor driving it and control electronics for controlling with or without feedback the electric motor is proposed, the control electronics being set up to carry out the method according to the invention.

The above-described method has numerous advantages. First, it improves the accuracy of the flow and/or head determination by counteracting disturbing influences on the system formed by the centrifugal pump and the connected hydraulic piping network, thereby reducing the noise in the determined flow and/or head signal. As a result, the signal requires less filtering, allowing a faster response of the centrifugal pump assembly to system condition changes or disturbances in the hydraulic piping network. Further, the periodic excitation signal may use a lower excitation amplitude than in the prior art, thereby reducing noise. As a result of the adjusting the model parameter during operation of the pump, any modelling inaccuracies in the pump-motor model which may be due to a scattering of the model parameters in series production and/or to wear due to ageing, for example of the bearings of the centrifugal pump, are also compensated for.

By repeatedly adjusting the model parameter(s), the pump-motor model is dynamic. This allows, among other things, to detect signs of ageing on the centrifugal pump and to compensate for a resulting error in the pump-motor model that increases over time. In this way, the accuracy of the flow rate and/or head determination is kept constantly high over the entire operating time of the pump. In addition, deposits on the impeller, e.g. of iron oxide, commonly known as “clogging,” can be detected, thus providing an early indication of the need for maintenance, especially of the overall system.

Suitably, the pump-motor model comprises at least a first equation enabling calculating the flow rate and a second equation enabling calculating the model speed. Suitably, these two equations are repeatedly evaluated cyclically. In terms of signals, this calculation can be performed in parallel.

For example, the first equation may be a flow equation in integral form. It is preferably based on a hydraulic differential equation that in particular describes a head or pressure balance (head and pressure are proportional) and is transformed into the integral form to be able to calculate the flow rate in a simple way.

Further preferably, the second equation may be a velocity equation in integral form. This is preferably based on a hydromechanical differential equation that in particular describes a torque balance and is converted into the integral form to be able to calculate the model speed in a simple manner.

For example, the first equation or volume flow equation can be used in the following integral form:

$${Q}_{mdl} = \frac{1}{{L}_{hyd}} {\int }_{0}^{t} ( ( a {ω}^{2} - {bQ}_{mdl} ω - {cQ}_{mdl}^{2} ) - {R}_{hyd} {Q}_{mdl}^{2} - {H}_{static} ) dt \qquad G 11$$

where

Q_{mdl} the flow rate of the centrifugal pump to be determined,

ω a speed or rotational frequency of the centrifugal pump (ω=2πn) ,

a, b, c are parameters that describe the hydraulic pump map (H(Q, ω)) by means of pump curves,

R_{hyd} the hydraulic resistance of the hydraulic system,

L_{hyd} the hydraulic inductance of the hydraulic system and

Hstatic is a geodetic head.

The numerical solution of this first equation G11 can be done by a discrete-time implementation using the so-called forward Euler integration, where the conveying stream Q_{mdl} on the left side of the equation at time k+1 is calculated from the conveying flow Q_{mdl} on the right side of the equation at time k. The numerically solvable discrete-time form of the first equation can then be:

$${Q}_{mdl} ( k + 1 ) = {Q}_{mdl} ( k ) + \frac{1}{{L}_{hyd}} ( ( a {ω}^{2} ( k ) - {bQ}_{mdl} ( k ) ω ( k ) - {cQ}_{mdl}^{2} ( k ) ) - {R}_{hyd} {Q}_{mdl}^{2} ( k ) - {H}_{static} ( k ) ) \cdot Δ t \qquad G11$$

Here Δt is the time interval between time k+1 and time k.

The model parameters a, b, c are known per se, since they represent the static mathematical relationship H=f(Q, ω) between delivery head H and flow rate Q for any given rotational speed win other words the so-called pump curve that is regularly measured at the factory for centrifugal pumps and consists of the sum of all pump curves, i.e. curves H_{ω}=fQ of constant speed that are specified by the manufacturer in the technical documentation of the pump. In contrast, the hydraulic resistance R_{hyd} of the system, the hydraulic inductance L_{hyd} of the system and its geodetic head Hstatic depend on the system itself, more precisely on its topology and condition, it being significantly dependent on the position of the valves in the system, so that its hydraulic resistance is variable.

Preferably, estimated values are used for the hydraulic resistance R_{hyd} and the hydraulic inductance L_{hyd} at the beginning of the method. By using the method according to the invention, any estimation error is compensated.

In the case of a closed pipe network, as is the case for example in a heating system or cooling system with a heat transfer medium circulating in a circuit, the geodetic head is zero, so that for this application H_{static}=0 can be set. The value for the geodetic head H_{static} can, for example, be manually set by a user on the control electronics of the centrifugal pump if it is constant. However, it is also possible for the control electronics to set the value for the geodetic head H_{static} itself, in particular to zero, based on an indication of the piping network or the application (heating system, cooling system) in which the centrifugal pump is operated. In the case of a variable geodetic head, this must be measured or otherwise determined.

To be able to specifically specify the delivery head in addition to or as an alternative to the flow rate, the first equation (volume flow equation) can be separated into a first and second partial equation, where the first partial equation describes the static hydraulic pump map for calculating the delivery head and the second partial equation is the dynamic volume flow equation using the calculated delivery head. The second partial equation can also be considered as the main equation as it retains integral form, whereas the first equation can be considered as a secondary equation as it provides a term required in the main equation.

For example, the first partial equation, hereafter Eq1a, and second partial equation, hereafter Eq1b can be used in the following form:

$${H}_{mdl} = a {ω}^{2} - {bQ}_{mdl} ω - {cQ}_{mdl}^{2} \qquad G11a$$

$${Q}_{mdl} = \frac{1}{{L}_{hyd}} {\int }_{0}^{t} ( {H}_{mdl} - {R}_{hyd} {Q}_{mdl}^{2} - {H}_{static} ) dt \qquad G11b$$

where H_{mdl} is the head of the centrifugal pump to be determined, more precisely a model size.

As already explained for the first equation Eq. 1, the numerical solution of the second partial equation Eq. 1b can also be carried out by a discrete-time implementation with the aid of the forward Euler integration, whereby the conveying current Q_{mdl} on the left-hand side of the equation at time k+1 is derived from the conveying flow Q_{mdl} on the right side of the equation at time k. The numerically solvable discrete-time form of the second partial equation G11b can then be:

### G11b:

$${Q}_{mdl} ( k + 1 ) = {Q}_{mdl} ( k ) + \frac{1}{{L}_{hyd}} ( {H}_{mdl} ( k ) - {R}_{hyd} {Q}_{mdl}^{2} ( k ) - {H}_{static} ( k ) ) \cdot Δ t$$

Here Δt is the time interval between time k+1 and time k.

The first subequation Eq. 1b can also be implemented in discrete time:

H_{mdl}(k)=aω²(k)−bQ_{mdl}(k)ω(k)−cQ_{mdl}²(k) G11a:

In terms of process technology, the two partial equations G11a, G11b can be evaluated one after the other. Preferably, the first partial equation G11a is evaluated first, i.e. the delivery head H_{mdl} is calculated based on an initial flow rate value Q_{mdl}(k=1)=Qₛₜₐᵣₜ which can be zero, for example. Subsequently, based on the determined delivery head value H_{mdl} the second partial equation G11b is evaluated, i.e. the new flow rate value Q_{mdl}(k+1) is determined.

In an alternative variant, or the evaluation of the first equation G11 or its first partial equation G11a, the actual speed ωᵣₑₐₗ is used as the rotational speed ω that can be supplied to the pump-motor model for this purpose. This actual speed ωᵣₑₐₗ can be measured or calculated by the motor control of the electric motor driving the centrifugal pump, which sets the torque in step a.

To ensure that the results are consistent, for the evaluation of the first equation Eq. 1 or its first partial equation Eq. la, the speed co can be used. the model speed ω_{mdl} which was previously calculated within the pump-motor model using the second equation or the speed equation G12. This is possible because the disturbance controller calculating the disturbance signal manages to compensate very well for any speed error, so that the model speed and the real speed are the same.

It should be noted that for the model-based determining the flow rate or the head, the other quantity must always also be determined, at least within the pump-motor model, but depending on whether the flow rate or the head or both quantities are to be determined as part of the method according to the invention, either only the flow rate or only the head or both quantities are output from the pump-motor model.

For example, the velocity equation can be used in the following integral form:

$${ω}_{mdl} = \qquad G12$$

$$\frac{1}{J} {\int }_{0}^{t} ( {T}_{mot} - ( {a}_{t} {Q}_{mdl} ω - {b}_{t} {Q}_{mdl}^{2} - {c}_{t} \frac{{Q}_{mdl}^{3}}{ω} + {v}_{i} {ω}^{2} + {v}_{s} ω - I \frac{dQ}{dt} ) + {T}_{D} ) dt$$

where

Tₘₒₜ the mechanical torque of the motor (motor torque) of the centrifugal pump,

T_{D} the calculated disturbance signal in the form of a moment (disturbance moment),

Q_{mdl} the flow rate of the centrifugal pump to be determined,
ω_{mdl} the model speed or rotational frequency of the centrifugal pump (ω=2πn),
ω a speed or rotational frequency of the centrifugal pump (ω=2πn),
aₜ, bₜ, cₜ are parameters that describe the static torque map (T(Q, ω)) of the centrifugal pump by means of torque curves,
νᵢ a quantity describing the friction between impeller and medium,
νₛ a quantity describing the bearing friction,
J the mass inertia of the rotating components of the centrifugal pump (impeller, shaft, rotor), and
I is the mass inertia of the pumped medium in the impeller.

The speed equation G12 describes in integral form a hydromechanical differential equation in the manner of a torque balance in which the deviation between the motor torque Tₘₒₜ and the theoretical pump torque T_{mdl} plus a modeling error-related disturbance torque T_{D} is integrated. The motor torque Tₘₒₜ is set by the motor control of the electric motor driving the centrifugal pump to achieve the setpoint speed, or is modulated directly, and to this extent is known from the motor control.

For evaluating the second equation G12, as with the first equation G11, the speed can be taken as ω, the actual speed ωᵣₑₐₗ, or the model speed ω_{mdl} can be used.

The second equation Eq. 2 can also be solved numerically by a discrete-time implementation using forward Euler integration, where the rotational speed ω_{mdl} on the left-hand side of the equation at time k+1 is calculated from the rotational speed ω_{mdl} on the right side of the equation at time k. The numerically solvable discrete-time form of the second equation G12 can then be:

$${ω}_{mdl} ( k + 1 ) = {ω}_{mdl} ( k ) + \frac{1}{J} ( {T}_{mot} ( k ) - ( {a}_{t} {Q}_{mdl} ( k ) ω ( k ) - {b}_{t} {Q}_{mdl}^{2} ( k ) - {c}_{t} \frac{{Q}_{mdl}^{3} ( k )}{ω ( k )} + {v}_{i} {ω}^{2} ( k ) + {v}_{s} ω ( k ) - I \frac{Q ( k ) - Q ( k - 1 )}{Δ t} ) + {T}_{D} ( k ) ) \cdot Δ t \qquad G12$$

Here is Δt is again the time interval between time k+1 and time k.

The theoretical pump torque T_{mdl} results from a model equation that is described in the second equation Eq2 by the inner bracket expression. In it, the model parameters aₜ, bₜ, cₜ are known per se, since they represent the static mathematical relationship T=f(Q, ω) between the torque T and the flow Q for an arbitrary rotational speed ωIn other words, they describe the torque map which can be measured at the factory for centrifugal pumps and which consists of the sum of all torque curves, i.e. curves T_{ω}=f of constant speed. The model parameters aₜ, bₜ, cₜ are on the one hand subject to series dispersion, i.e. they differ slightly from centrifugal pump to centrifugal pump due to tolerances, in particular by a few percent. On the other hand, they are subject to change due to ageing, in particular due to bearing wear and deposits on the impeller. The quantity describing the friction between impeller and medium νᵢ and the quantity describing the bearing friction (viscous friction in the hydrodynamic plain bearing) νₛ can also be determined by measuring the centrifugal pump at the factory and are known quantities in this respect. The mass inertia J can be calculated or measured from design data of the centrifugal pump and is therefore also available from the manufacturer. The same applies to the mass inertia I of the pumped medium in the impeller that is, however, negligibly low, so that the term

$$I \frac{dQ}{dt}$$

can be set to zero.

To simplify the calculation of the velocity equation G12, it can be separated into a first and second partial equation G12a, G12b, where the first partial equation G12a describes the static hydromechanical pump characteristic field (torque characteristic field) for calculating the theoretical pump torque and the second partial equation G12b is the dynamic velocity equation using the calculated theoretical pump torque. The second partial equation can also be considered as the main equation in this case, since it keeps the integral form, whereas the first equation can be considered as a secondary equation, since it provides a term needed in the main equation.

For example, the first partial equation G12a and second partial equation G12b can be used in the following form:

$${T}_{mdl} = {a}_{t} {Q}_{mdl} ω - {b}_{t} {Q}_{mdl}^{2} - {c}_{t} \frac{{Q}_{mdl}^{3}}{ω} + {v}_{i} {ω}^{2} + {v}_{s} ω - I \frac{dQ}{dt} \qquad G12a$$

$${ω}_{mdl} = \frac{1}{J} {\int }_{0}^{t} ( {T}_{mot} - {T}_{mdl} + {T}_{D} ) dt \qquad G12b$$

where T_{mdl} is the theoretical pump torque of the centrifugal pump to be calculated, more precisely a model quantity.

The numerical solution of the second partial equation Eq. 2b can again be done by a discrete-time implementation using the forward Euler integration, where the rotational speed ω_{mdl} on the left side of the equation at time k+1 is calculated from the rotational speed ω_{mdl} on the right side of the equation at time k. The numerically solvable discrete-time form of the second partial equation G12b can then be:

$${ω}_{mdl} ( k + 1 ) = {ω}_{mdl} ( k ) + \frac{1}{J} ( {T}_{mot} ( k ) - {T}_{mdl} ( k ) + {T}_{D} ( k ) ) \cdot Δ t \qquad G12b$$

The first subequation Eq. 2a can also be implemented in discrete time:

$${T}_{mdl} ( k ) = {a}_{t} {Q}_{mdl} ( k ) ω ( k ) - {b}_{t} {Q}_{mdl}^{2} ( k ) - {c}_{t} \frac{{Q}_{mdl}^{3} ( k )}{ω ( k )} + {v}_{i} {ω}^{2} ( k ) + {v}_{s} ω ( k ) - I \frac{Q ( k ) - Q ( k - 1 )}{Δ t} \qquad G12a$$

where the term

$$I \frac{Q ( k ) - Q ( k - 1 )}{Δ t}$$

can also be left out. In terms of process technology, evaluation of the two partial equations of the velocity equation can be carried out one after the other. Preferably, the first partial equation G12a is evaluated first, i.e. the pump torque is calculated, on the one hand using an initial flow rate value Q_{mdl}(k=1)=Qₛₜₐᵣₜ which can be zero, for example, and on the other hand based on an initial speed value ω_{mdl}(k=1)=ωₛₜₐᵣₜ greater than zero. Subsequently, based on the determined pump torque T_{mdl} the second partial equation Eq2b is evaluated, i.e. the new model speed ω_{mdl}(k+1) is determined.

To calculate the disturbance signal, the difference between the actual speed and the model speed may be fed to a controller containing at least one integral component. For example, the controller may be an I, PI or PID controller as is commonly known in control engineering. The disturbance signal may be the output signal of the controller or calculated from this controller output signal. The controller may be initialized with the value zero. If there is no difference between the model speed and the actual speed, the disturbance signal remains unchanged. If the difference is greater than zero, the value of the disturbance signal increases; if it is less than zero, the value of the disturbance signal decreases. In this respect, the controller can be described as a “disturbance controller” which compensates for the deviation between the real pump and the pump model and brings the model speed into line with the actual speed. The controller output is thus a measure of the (torque) deviation or disturbance of the model. By evaluating this disturbance according to the invention, the model can be dynamically adjusted.

As mentioned above, in one embodiment, the output signal of this controller may form the disturbance signal T_{D}. Since this signal T_{D} is part of a torque equation, the physical quantity of the controller output is a torque or “disturbance torque,” because a controller output quantity always has the dimension of the manipulated variable on which the controller acts. In another embodiment, the disturbance signal may be formed by multiplying the output signal of this controller by the actual speed, so that this disturbance signal represents a power. Thus, in this case, the disturbance signal P_{D} may be considered as a “disturbance power.” Thus, a basic idea of the method according to the invention is to adjust the at least one model parameter, or even several model parameters at the same time, in such a way that no disturbance torque T_{D} and/or no disturbance power P_{D} is present. In other words, the pump-motor model is continuously adjusted so that it always replicates reality and compensates for external disturbance effects on the centrifugal pump as well as any model errors. The pump-motor model is therefore dynamic in this respect.

According to a further development of the method, the combination of the two embodiments mentioned is also possible. Thus, in step d. a first disturbance signal T_{D} and a second disturbance signal P_{D} can be determined by feeding the difference between the model speed and the actual speed to a controller containing at least one integral component, the output signal of this controller forming the first disturbance signal T_{D} and the second disturbance signal P_{D} then being formed by multiplying the output signal of this controller by the actual speed. In other words, the second disturbance signal can be regarded as calculated from the first disturbance signal. Two disturbance signals T_{D}, P_{D} are then present that can be further processed separately from each other and each offer the possibility of adjusting or tracking one or more model variables of the pump-motor model.

Preferably, a correction signal T_{D1 sin} is determined from the disturbance signal T_{D} and used to adapt a model parameter of the pump-motor model. It is further possible that two or more correction signals T_{D1 sin}, T_{D1 cos} are determined from the disturbance signal T_{D} and each used to adjust a model parameter of the pump-motor model. In this way, two or a number of different model parameters corresponding to the number of correction signals can consequently be adjusted simultaneously. Finally, it is also possible that one, two or even more correction signals T_{D1 sin}, T_{D1 cos}, P_{D1 sin}, P_{D1 cos} are determined from each of the disturbance signals T, P_{DD}, and that each correction signal T_{D1 sin}, T, P, P_{D1 cos D1 sin D1 cos} is used to adjust one particular model parameter R_{hyd}, J, L_{hyd}, cₜ of the pump-motor model. This allows three, four or more model variables of the pump-motor model to be adjusted simultaneously and independently.

In principle, any of the correction signals can be used to adjust one of the model parameters. However, it should be noted that those correction signals which represent an active component, i.e. are in phase with the excitation of the speed or torque, correct those model parameters which predominantly act on the active power. In contrast, correction signals that represent a reactive power, i.e. are 90° out of phase with the excitation, can only correct model parameters that predominantly influence the reactive power.

For example, the model parameter to be adjusted may be the hydraulic resistance R_{hyd} of the piping network or the model parameter cₜ. The hydraulic resistance R_{hyd} indicates the steepness of the characteristic curve of the piping system. It changes if the piping system has controlled valves, as is the case in heating or cooling systems, for example. Tracking the hydraulic resistance R_{hyd} in the pump-motor model is therefore of particular advantage to ensure the accuracy of the head and/or flow rate determination. The model parameter cₜ is subject to series variation from centrifugal pump to centrifugal pump and also changes with the age of the centrifugal pump, whereas the other parameters aₜ and bₜ have no strong dependence and remain almost constant. The model parameters R_{hyd}, cₜ affect the active power. Therefore, in this case, it is provided that in step e. the sine or cosine signal that is in phase with the excitation signal is used. In other words, in step e., the sine signal is used when the excitation signal is also a sine signal, and the cosine signal is used when the excitation signal is also a cosine signal.

To adjust both of the above-described model variables R_{hyd}, cₜ in a preferred embodiment, the hydraulic resistance R_{hyd} can be adjusted as a function of a first correction signal P_{D1 sin} formed from the second disturbance signal P_{D}, and the model parameter cₜ can be adjusted as a function of a first correction signal T_{D1 sin} formed from the first disturbance signal T_{D}. However, the reverse is also possible, i.e. that the hydraulic resistance R_{hyd} is adapted as a function of the first correction signal T_{D1 sin} formed from the first disturbance signal T_{D}, and the model parameter cₜ is adapted as a function of the first correction signal P_{D1 sin} formed from the second disturbance signal P_{D}. However, the former variant has the advantage that the cₜ—term

$${c}_{t} \frac{{Q}^{3}}{ω}$$

of the torque equation (Eq. 2) in the corresponding power equation due to the multiplication with the speed (P=T·ω) only acts as cₜQ³ and is dropped out in the integration of this power equation. Furthermore, it is of course also possible that in one embodiment only one of the these model parameters R_{hyd}, cₜ is adjusted and then either the first correction signal T_{D1 sin} of the first disturbance signal T_{D}, or the first correction signal P_{D1 sin} of the second disturbance signal P_{D} is used for this purpose.

According to one embodiment, the model parameter to be adjusted can be the mass inertia J of the centrifugal pump or the hydraulic inductance L_{hyd} of the pipeline network. An adaptation or tracking of the inertia J of the centrifugal pump as a model parameter has the advantage that ageing phenomena on the centrifugal pump, such as deposits on the impeller (clogging) or bearing wear, can be detected, since these increase the inertia. If the model parameter “inertia” is thus increased within the scope of the method, an indication, in particular maintenance information, can be output on the centrifugal pump if a predetermined limit value is exceeded. An adaptation or tracking of the hydraulic inductance as a model parameter has the advantage that structural changes to the piping system can be detected, for example as a result of a fault by which a network section is permanently cut off from the rest, or as a result of a conversion or extension of the pipe power network. The detection of an increasing or decreasing hydraulic inductance can also be used to issue an indication at the centrifugal pump, for example, for the purpose of checking the operating setting of the centrifugal pump and/or to directly adjust the control of the centrifugal pump, for example, by increasing or decreasing its reference speed or a set control characteristic. These model parameters J, L_{hyd}, influence the reactive power. Therefore, in this case, it is provided that in step e. the sine or cosine signal that is 90° out of phase with respect to the excitation signal is used. In other words, in step e., the cosine signal is used when the excitation signal is a sine signal, and the sine signal is used when the excitation signal is a cosine signal.

To adjust both these model variables J, L_{hyd} in a preferred embodiment, the inertia J can be adjusted as a function of a second correction signal P_{D1 cos} formed from the second disturbance signal P_{D}, and the hydraulic impedance L_{hyd} can be adjusted as a function of a second correction signal T_{D1 cos} formed from the first disturbance signal T_{D}. However, it is also possible the other way round, i.e. that the inertia J is adjusted as a function of the second correction signal T_{D1 cos} formed from the first disturbance signal T_{D}, and the hydraulic impedance L_{hyd} is adjusted as a function of the second correction signal P_{D1 cos} formed from the second disturbance signal P_{D}. Furthermore, it is of course also possible that in one embodiment only one of these model parameters J, L_{hyd} is adapted and then either the second correction signal T_{D1 cos} of the first disturbance signal T_{D}, or the second correction signal P_{D1 cos} of the second disturbance signal P_{D} is used for this purpose.

In one embodiment, it may further be provided that all four above-described model parameters R_{hyd}, cₜ, J, L_{hyd} are each adjusted simultaneously in dependence on the above-described correction signals T_{D1 sin}, T_{D1 cos}, P_{D1 sin}, P_{D1 cos}, for example.

the hydraulic resistance R_{hyd} as a function of the first correction signal P_{D1 sin} formed from the second disturbance signal P_{D}, the model parameter cₜas a function of the first correction signal T_{D1 sin} formed from the first disturbance signal T_{D}

the inertia J as a function of the second correction signal P_{D1 cos} formed from the second disturbance signal P_{D} and

the hydraulic impedance L_{hyd} as a function of the second correction signal T_{D1 cos} formed from the first disturbance signal T_{D}.

In mathematical terms, step e. is a sine/cosine transformation that is performed discretely on a processor. In the following, however, the continuous-time representation of the mathematical relationships is used for the sake of simplicity.

Preferably, the correction signal, or in the case of several correction signals of the respective correction signal, is determined by using a sine or cosine signal with a multiple of the excitation frequency. If, for example, the excitation signal has the frequencyω t, then in this case the sine or cosine signal which is multiplied by the interference signal, or in the case of two interference signals by the respective interference signal, also has this simple frequencyω t, hereinafter also referred to as the fundamental frequency. However, it is also possible, alternatively or to obtain further correction signals, to additionally use a sine or cosine signal with double, triple or another nth multiple of the fundamental frequency, i.e. with a frequency 2ω, 3ω or nω t. However, since the amplitude of the correction signal is largest when the fundamental frequency is used, the use of a sine or cosine signal with one times the excitation frequency, i.e. the fundamental frequency, is the preferred choice. As described above, in this case already two model parameters per disturbance signal (one model parameter when using a sine signal with fundamental frequency and one when using a cosine signal with fundamental frequency in step e.), i.e. four model parameters for two disturbance signals (disturbance torque and disturbance power). If, in addition, twice the fundamental frequency is used, two further model parameters can be adapted, and in the case of two disturbance signals even four.

In this case, the correction signals can be formed mathematically as follows:

using the fundamental frequency of the excitation signal:
the first correction signal T_{D1 sin} of the first disturbance signal T_{D}:

$${T}_{D 1 sin} = \frac{1}{T} {\int }_{0}^{T} {T}_{D} \cdot sin ( {ω}_{A} t ) dt$$

the second correction signal T_{D1 cos} of the first disturbance signal T_{D}:

$${T}_{D 1 cos} = \frac{1}{T} {\int }_{0}^{T} {T}_{D} \cdot cos ( {ω}_{A} t ) dt$$

the first correction signal P_{D1 sin} of the second disturbance signal P_{D}:

$${P}_{D 1 sin} = \frac{1}{T} {\int }_{0}^{T} {P}_{D} \cdot sin ( {ω}_{A} t ) dt$$

the second correction signal P_{D1 cos} of the second disturbance signal P_{D}:

$${P}_{D 1 cos} = \frac{1}{T} {\int }_{0}^{T} {P}_{D} \cdot cos ( {ω}_{A} t ) dt$$

and using the nth multiple of the fundamental frequency of the excitation signal:
a correction signal T_{Dn sin} of the first disturbance signal T_{D}:

$${T}_{D n sin} = \frac{1}{T} {\int }_{0}^{T} {T}_{D} \cdot sin ( n {ω}_{A} t ) d t$$

a correction signal P_{Dn cos} of the second disturbance signal P_{D}:

$${P}_{D n c o s} = \frac{1}{T} {\int }_{0}^{T} {P}_{D} \cdot cos ( n {ω}_{A} t ) d t$$

From a mathematical point of view, the calculation of the least one or more correction signals is a type of Fourier analysis, but integrals are only calculated for a few individual frequencies. These integrals can be considered as Fourier integrals.

It is also possible to use the DC component of the disturbance signal to adjust or track a specific model parameter.

Preferably, the adaptation of the or the corresponding model parameter R_{hyd}, J, L_{hyd}, cₜ is carried out using a controller containing at least one integral component, to which the or the respective correction signal T_{D1 sin}, T_{D1 cos}, P_{D1 sin}, P_{D1 cos}, wherein the controller output signal is multiplied by an initial value for the or the corresponding model parameter (R_{hyd}, J, L, c_{hydt}) to obtain the adjusted model parameter R_{hyd}, J, L_{hyd}, cₜ. The initial value may be a factory measured value (for inertia J or cₜ) or an average value assumed for the intended operation of the centrifugal pump (for R_{hyd}, L_{hyd}). The controller can be an I, PI or PID controller. Due to the integral component (I component) in the controller, it acts like an integrator.

The controller output signal can be understood as a correction factor K for the model parameter. The controller can be initialized with the value 1 at the beginning of the procedure, so that the controller output signal K=1 and the multiplication with the initial value results in the adjusted model parameter being equal to the initial value at the beginning of the procedure, i.e. remaining unchanged. If the correction signal is zero, the controller output signal remains at K=1. However, if the correction signal is greater than 0, the correction factor K increases, and if the correction signal is less than 0, the correction factor K decreases. As a result of the multiplication of the correction factor K by the initial value, the model parameter is then increased or decreased. The controller can thus be referred to as a “parameter controller.” The advantage of this arrangement is that the controller can be easily limited. For example, the correction factor can be limited to a factor of 5, where permissible values can preferably be between ⅕ and 5. This makes it possible to determine how far the value has moved away from the initial assumption, i.e. the initial value.

It should be noted that, in the context of the present description, the terms “have,” “comprise” or “include” in no way exclude the presence of other feature. Furthermore, the use of the indefinite article in relation to a subject does not exclude its plural.

### BRIEF DESCRIPTION OF THE DRAWING

Further features, characteristics, effects and advantages of the invention will be explained in more detail below with reference to examples or embodiments and the accompanying figures. The reference signs contained in the figures retain their meaning from figure to figure. In the figures, reference signs always denote the same or at least equivalent components, areas, directions or locations. In the drawing:

FIG. 1 is a schematic representation of a centrifugal pump within a closed hydraulic system;

FIG. 2 is a signal flow diagram of a first embodiment of the method according to the invention with singular model parameter adjustment;

FIG. 3 is a signal flow diagram with an embodiment of the pump-motor model 9 in FIG. 2;

FIG. 4 is an embodiment of the disturbance controller 10 in FIG. 2;

FIGS. 5-8 show different versions of the parameter controller 12 in FIG. 2;

FIG. 9 is a signal flow diagram of a second embodiment of the method according to the invention with singular model parameter adjustment and missing actual speed feed to the pump-motor model 9;

FIG. 10 is a signal flow diagram with an embodiment of the pump-motor model 9a in FIG. 9 with internal use of the model speed;

FIG. 11 is a signal flow diagram of a third embodiment of the method according to the invention comprising a multi-model parameter adaptation and a single disturbance variable on the output side of the disturbance controller 10;

FIG. 12 is a signal flow diagram of a fourth embodiment of the method according to the invention with multi-model parameter adaptation and two disturbance variables on the output side of the disturbance controller 10a;

FIG. 13 is an embodiment of the disturbance controller 10a in FIG. 12; and

FIG. 14 is a signal flow diagram showing an embodiment of the pump-motor model 9b in FIGS. 11 and 12 with multi-model parameter fitting.

### SPECIFIC DESCRIPTION OF THE INVENTION

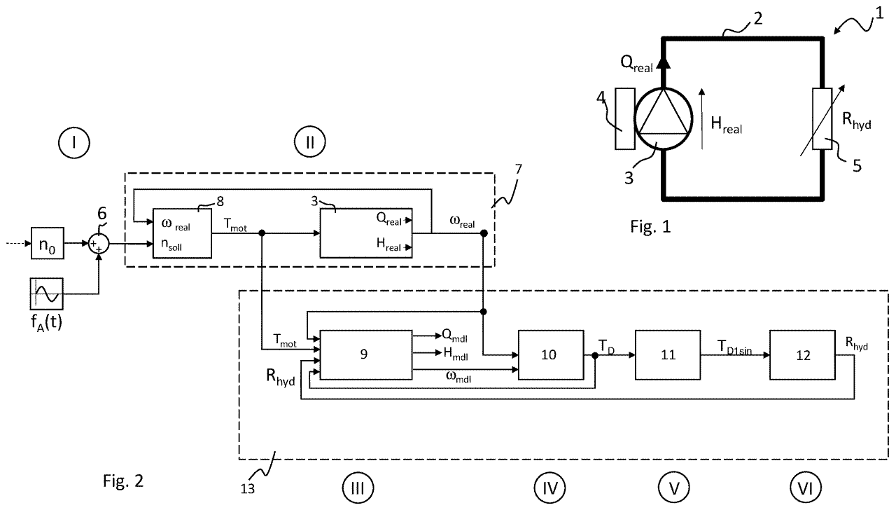

FIG. 1 shows a purely schematic representation of a centrifugal pump 3, 4 within a closed hydraulic system 1 in which the centrifugal pump 3, 4 circulates a fluid. The hydraulic system 1 may be, for example, a heating system or a cooling system for buildings, although for simplicity system components such as a heating source or chiller, heat exchanger, hydraulic separator, valves, etc. are omitted. However, the hydraulic system 1 comprises a piping network 2 extending from the centrifugal pump 3, 4 to a number of consumers (flow), such as radiators, heating circuits of a floor heating system or cooling circuits of a cooled ceiling and extending from these consumers back to the centrifugal pump 3, 4 (return). In this case, the centrifugal pump 3, 4 is intended to convey a heat transfer medium, such as water, to the consumers. Control valves, such as thermostatic valves or electrothermal actuators, are associated with these consumers to adjust the flow rate through the respective consumer or through a group of consumers. Due to the varying degree of opening of these control valves, the hydraulic load 5 to be served by the centrifugal pump 3, 4 changes according to the demand from the consumers, which for simplicity is symbolized in FIG. 1 by a single, but variable hydraulic resistance R_{hyd}. It describes the slope of the so-called pipe network parabola of the hydraulic system 1, generally also called system characteristic curve or system curve.

It should be noted that the hydraulic system may equally be an open system, as in the case of a borehole pump, a sewage-lift station or a drinking-water pressure-boosting system.

The centrifugal pump 3, 4 comprises a centrifugal pump 4 together with an electric motor drive and pump or control electronics 4 for controlling with or without feedback the electric motor that are also set up for carrying out the method according to the invention. The electric motor may, for example, be a three-phase, permanently excited, electronically commutated synchronous motor. The control electronics 4 comprise a frequency converter for setting a specific speed of the electric motor. In operation, the centrifugal pump 4 generates a differential pressure between its suction and discharge sides, also referred to as head Hᵣₑₐₗ that, depending on the hydraulic resistance R_{hyd} of the pipe network 2 connected to the centrifugal pump 4, results in a flow rate Qᵣₑₐₗ.

A signal flow diagram illustrating the sequence of a first embodiment of the method according to the invention for determining the current delivery head Hᵣₑₐₗ and/or the current delivery flow Qᵣₑₐₗ as accurately as possible by calculation is shown in FIG. 2. The method can be roughly divided into six process sections I to VI that are explained individually below. The process sections I to IV basically take place simultaneously and are repeatedly executed cyclically one after the other as a result of their program-technical processing by software in the control electronics 4, in particular at the clock speed of a processor not shown in the control electronics 4 on which the process according to the invention runs.

In the first process section I, a periodic excitation of the hydraulic system 1 takes place. In this embodiment, this takes place by applying a periodic excitation signal f_{A} of a specific excitation frequencyω_{A} to a reference rotational speed n₀ of the centrifugal pump 3, 4 to obtain a modulated set rotational speed nₛₒₗₗ and thus to modulate the actual rotational speed nᵣₑₐₗ of the centrifugal pump 3, in particular to cause it to fluctuate periodically. It should be noted at this point that in various places in the figures the rotational frequencyω is used instead of the rotational speed n that due to the relationshipω=2π n does however correspond to the rotational speed and is understood to be synonymous with it, which is why in the following we refer generally to the “rotational speed ω.”

The periodic excitation f_{A} has the effect of modulating the differential pressureΔ p of the centrifugal pump 3 or its delivery head Hᵣₑₐₗ proportional thereto that, depending on the modulation amplitude and frequency, results in a signaling response of the hydraulic system 1 that in turn is reflected in the torque required to set the modulated setpoint speed nₛₒₗₗ, and also in the electrical power consumption of the centrifugal pump, from which the delivery flow Q can be determined. This basic principle is described in U.S. Pat. No. 10,184,476, to which reference is hereby made.

The reference speed no can be an externally specified speed for the centrifugal pump 3, 4 or a speed determined internally in the control electronics 4. It can, for example, originate from a characteristic curve control upstream of the speed control that, for example, sets the delivery head H as a function of the delivery flow Q according to a defined characteristic curve in the so-called HQ diagram, or result from an automatic control that sets the delivery head H as a function of other criteria, e.g. the change in delivery flow dQ/dt.

For example, the excitation signal f_{A} can be a sinusoidal signal of the form f_{A}=n₁·sin(ω_{A}·t), where n₁ is the excitation amplitude and ω_{A} is the excitation frequency. However, the excitation need not be sinusoidal. Another periodic waveform such as a square wave, trapezoidal wave, triangular wave, sawtooth wave or shark fin waveform are also possible. The periodic excitation of the system 1 or application of the excitation signal f_{A} to the reference speed no is done by superimposition in an adder 6, to which the reference speed no and the excitation signal f_{A} are each supplied in terms of signals. The output variable of this adder 6 is the modulated reference speed nₛₒₗₗ=n₀+n₁·sin(ω_{A}·t). This forms the input variable for the second process step II.

In this second method section II, the motor control 7 known per se is carried out for setting the modulated setpoint speed nₛₒₗₗ, for example using a vectorial, in particular field-oriented control. Since the actual speed ωᵣₑₐₗ is the controlled variable in this case, it is directly available from the field-oriented control, either based on a measurement by means of an encoder, by evaluating the voltage induced back into the stator coils by the rotor magnetic field (back EMF) or based on a calculation using a known algorithm for sensorless speed control. The motor control 7 comprises at least one speed controller 8, to which the modulated reference speed nₛₒₗₗ is fed and which determines the torque Tₘₒₜ required to achieve the modulated reference speed nₛₒₗₗ as a function of the deviation of the actual speed ωᵣₑₐₗ from the reference speed nₛₒₗₗ or, of course, ωₛₒₗₗ. The actual speed ωᵣₑₐₗ is thus also an input variable of the speed controller 8. The speed controller 8 may, for example, be a P, PI or PID controller, in which case the torque Tₘₒₜ is the manipulated variable. It can also be a PI-R controller that has a resonance component at the excitation frequency ω_{A} to achieve the lowest possible control deviation.

The determined torque Tₘₒₜ is then adjusted by the motor control 7 on the drive of the centrifugal pump 3 that in FIG. 2 forms a physical system component. Depending on this torque Tₘₒₜ, a corresponding (actual) speed ωᵣₑₐₗ of the centrifugal pump 3 results that then generates a delivery head Hᵣₑₐₗ and, depending on the load 5 in the form of the hydraulic resistance R_{hyd}, a corresponding delivery flow Qᵣₑₐₗ. The determined actual speed ωᵣₑₐₗ, is fed to the speed controller 8 to determine the deviation from the set speed nₛₒₗₗ and to adjust the torque Tₘₒₜ. Such a motor control 7 is known per se.

According to the invention, the determined torque To is further fed to a mathematical pump-motor model 9 which simulates the hydromechanical behavior of the centrifugal pump 3. This is a third section III of the method according to the invention and is part of a model-based operating point determination device 13 that is implemented in the control electronics 4 and is set up to determine the delivery head H_{mdl} and/or the flow rate Q_{mdl} of the centrifugal pump 3 from the pump-motor model 9. In control terms, this pump-motor model 9 represents a so-called observer which ideally enables observation of all state variables of the centrifugal pump 3, i.e. also non-measurable state variables. In particular, the pump-motor model 9 enables an estimation of the actual head Hᵣₑₐₗ, the actual flow Qᵣₑₐₗ and the actual speed ωᵣₑₐₗ in the form of their respective model quantities H_{mdl}, Q_{mdl} and ω_{mdl}, it also being referred to as the model speed ω_{mdl}.

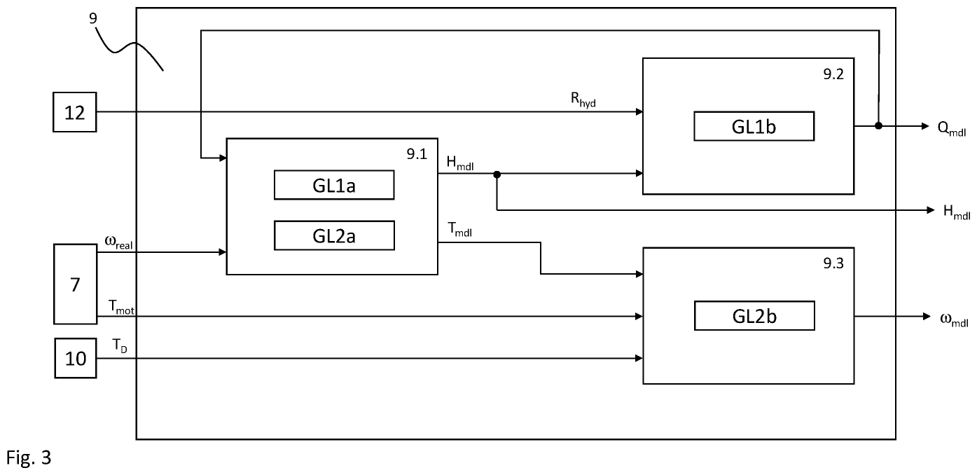

One embodiment of the pump-motor model 9 is illustrated in FIG. 3. It comprises a system of equations based on a first differential equation G11a, G11b and a second differential equation G12a, G12b, each of which is transformed into an integral form to form a first and a second integral equation to simplify their calculation. The first integral equation Eq1a, Eq1b is based on a hydraulic differential equation describing a pressure balance in system 1 expressed in head. It forms a volumetric flow equation since it allows the calculation of the flow rate Q_{mdl}. The second integral equation Eq2a, Eq2b is based on a hydromechanical differential equation describing a torque balance in system 1 considering friction losses. It forms a velocity equation since it allows the calculation of the model speed ω_{mdl}. The two integral equations are calculated successively in a discrete-time manner using forward Euler integration.

To simplify the evaluation of the two integral equations, they are each divided into a static first partial equation G11a, G12a (secondary equation) and a dynamic second partial equation G11b, G12b (main equation) that has the integral form. In this case, the first partial equation G11a, G12a and then the second partial equation G11b, G12b are each calculated in terms of signal technology, whereby the result of the solution of the respective first partial equation G11a, G12a is used for the calculation of the respective second partial equation G11b, G12b, as is made clear below with reference to FIG. 3, which is why the first partial equations can be regarded as secondary equations to the second partial equations that in turn form the main equations due to their integral form.

In total, the system of equations thus consists of the following four subequations G11a, G11b, G12a, G12b, where the first two subequations G11a, G11b form a set describing the first integral equation, and the second two subequations G12a, G12b form a set describing the second integral equation. In the discrete-time implementation, the partial equations are as follows

$${H}_{m d l} ( k ) = a {ω}^{2} ( k ) - b {Q}_{m d l} ( k ) ω ( k ) - c {Q}_{m d l}^{2} ( k ) \qquad G 11 a$$

$${Q}_{m d l} ( k + 1 ) = {Q}_{m d l} ( k ) + \frac{1}{{L}_{h y d}} ( {H}_{m d l} ( k ) - {R}_{h y d} {Q}_{m d l}^{2} ( k ) - {H}_{s t a t i c} ( k ) ) \cdot Δ t \qquad G 11 b$$

$${T}_{m d l} ( k ) = {a}_{t} {Q}_{m d l} ( k ) ω ( k ) - {b}_{t} {Q}_{m d l}^{2} ( k ) - {c}_{t} \frac{{Q}_{m d l}^{3} ( k )}{ω ( k )} + {v}_{i} {ω}^{2} ( k ) + {v}_{s} ω ( k ) \qquad G 12 a$$

$${ω}_{m d l} ( k + 1 ) = {ω}_{m d l} ( k ) + \frac{1}{J} ( {T}_{m o t} ( k ) - {T}_{m d l} ( k ) + {T}_{D} ( k ) ) \cdot Δ t \qquad G 12 b$$

where

H_{mdl} the delivery head to be determined H_{mdl} of the centrifugal pump 3,

Q_{mdl} the flow rate of the centrifugal pump 3 to be determined,

ω a speed or rotational frequency of the centrifugal pump (ω=2πn) ,

ω_{mdl} the model speed of the centrifugal pump 3,
a, b, c are parameters that describe the hydraulic pump map (H(Q, ω)) by means of pump curves,

R_{hyd} is the hydraulic resistance of the hydraulic system 1,

L_{hyd} the hydraulic inductance of the hydraulic system 1 and

H_{static} is a geodetic head,

T_{mdl} the theoretical pump torque of the centrifugal pump 3 to be calculated,

Tₘₒₜ the mechanical torque of the motor (motor torque) of the centrifugal pump,

T_{D} a calculated disturbance signal in the form of a moment (disturbance moment),

aₜ, bₜ, cₜ are parameters describing the static torque map (T(Q, ω)) of the centrifugal pump 3 by means of torque curves,

νᵢ a quantity describing the friction between impeller and medium,

νₛ a quantity describing the bearing friction,

J the mass inertia of the rotating components of the centrifugal pump 3 (impeller, shaft, rotor), and

k is a discrete time and

Δt is the time interval between one time k and the next time k+1.

In the first partial equation G11a of the first integral equation, further pressure terms can be considered, if necessary, to further adapt the pump-motor model 9 to reality. Furthermore, in the first partial equation G12a of the second integral equation G12 further terms (e.g. for friction) can be considered if necessary.

The pump-motor model 9 in FIG. 3 comprises three function blocks 9.1, 9.2, 9.3. In the second function block 9.2 the main equation G11b of the first integral equation (volume flow equation) is evaluated. Furthermore, in the third function block 9.3, the main equation G12b of the second integral equation (velocity equation) is evaluated. The second and third function block 9.2, 9.3 are preceded by the first function block 9.1, in which the two secondary equations G11a, G12a (pressure and torque characteristics) of the integral equations are evaluated. The functional summary of the calculation of these two partial equations G11a, G12a in the first function block 9.1 is done here because both partial equations G11a and G12a need the actual speedω and the flow rate Q to be calculated. However, the partial equations G11a and G12a could just as well be calculated in separate function blocks in terms of signal technology.

The first partial equation G11a of the first integral equation (volume flow equation) describes the speed-dependent relationship between flow rate Q and head H, or more precisely the pump characteristic diagram, i.e. for each speed co the dependence of the head H on the flow rate Q, this relationship being referred to as the pump curve Hω(Q). Along such a pump curve Hω the speed w is constant. All pump curves Hω form the pump map H(ω, Q). The pump characteristic diagram H(ω, Q) is usually measured at the factory and specified in the technical documentation of a centrifugal pump 3. The model parameters a, b, c that mathematically describe the pump curve H(ω, Q), are therefore known.

To calculate the model quantity H_{mdl} by means of the partial equation G11a in the first function block 9.1, the speedω and the flow rate Q are required. In the embodiment according to FIGS. 2 and 3, the speedω is provided as the actual speed ωᵣₑₐₗ is provided by the motor control unit 7 or fed to the first function block 9.1. The calculated feed flow Q_{mdl} from the output of the second function block 9.2 is used as the feed flow Q and is also supplied to the first function block 9.1, wherein the feed flow Q_{mdl} is zero at the start of the process or a defined initial value is used. The calculated model variable H_{mdl} is output at the output of the first function block 9.1 and thus also forms the delivery head to be determined in accordance with the invention H_{mdl}which is output at the output of the pump-motor model 9 as the first output variable.

In addition, the calculated delivery head model variable H_{mdl} is transferred to the second function block 9.2, in which it is used to calculate the delivery flow Q_{mdl} by means of the second partial equation G11b of the first integral equation. For the evaluation of this partial equation G11b, the hydraulic resistance R_{hyd}, the hydraulic impedance L_{hyd}, the current flow rate Q_{mdl} and the geodetic head Hstatic are also required.

The second partial equation G11b of the first integral equation is based on the hydraulic differential equation:

$$H ( n , Q ) = {R}_{h y d} {Q}^{2} + {L}_{h y d} \frac{d Q}{d t} + {H}_{s t a t i c}$$

that describes the system characteristic curve of the pipeline network 2 or the hydraulic system 1 that depends significantly on the position/degree of opening of the valves on the consumer side, i.e. on the hydraulic resistance R_{hyd}.

The geodetic head H_{static} is the minimum head H that must be reached in order for a flow (Q>0) to be possible at all. In closed hydraulic systems, i.e. those pipe networks in which the pumped medium circulates, such as in a heating or cooling system, the geodetic head H_{static} is zero and can be neglected in this case. In the case of an open system, the geodetic head H_{static} can, for example, be measured or specified on the pump electronics 4 of the centrifugal pump by a user.

The hydraulic resistance R_{hyd} and the hydraulic impedance L_{hyd} are initially unknown, since these parameters are part of the user's hydraulic system 1 that the pump manufacturer does not know. The hydraulic inductance L_{hyd}, together with the volume flow, is a measure of the kinetic energy stored in the flowing water mass. Provided that the system is not changed structurally, the hydraulic impedance L_{hyd} consequently does not change either. In the embodiment according to FIGS. 2 and 3, it can be determined by a simple estimation. In contrast, the hydraulic resistance R_{hyd} changes dynamically during operation of the system 1 as a function of the demand of the consumers, in particular the heating or cooling demand, i.e. as a function of the position of the control valves on the consumer side which adjust the volume flow through the consumers. However, when the valves close completely, the inductance L_{hyd} also changes.

In the first embodiment, the hydraulic resistance R_{hyd}is a model parameter of the pump-motor model 9 which is dynamically adapted according to the invention. It is repeatedly redetermined by a parameter controller 12 and fed to the pump-motor model 9, more specifically to the second function block 9.2, to be used in partial equation Eq1b. Since the hydraulic resistance R_{hyd} is unknown at the beginning of the process, any initial value can be used for R_{hyd}. This is because during the procedure its value is corrected by the parameter controller 12 towards the real value, as will be explained further below.

The volumetric flow value Q to be used in equation G11b is the volumetric flow value that is valid at the current point in time k. Partial equation G11b can thus be evaluated and the new volumetric flow Q_{mdl}(k+1) can be determined. It thus represents the output signal of the second function block 9.2 as well as the second output variable of the pump-motor model 9.

The first part G12a of the second integral equation (velocity equation) describes the speed-dependent relationship between torque T and flow rate Q. It is therefore basically a torque equation. Like partial equation Eq. 1a, it requires the current rotational speed wand the current flow rate Q(k). As explained for the individual equation G11a, the speedω is the actual speed supplied by the motor control 7 to the first function block 9.1 ωᵣₑₐₗ and as the current delivery flow Q the delivery flow Q_{mdl}(k+1) from the output of the second function block 9.2 last calculated with partial equation G11b is used.

The term νᵢω² in partial equation Eq. 2a describes the friction between impeller and medium, the term νₛω describes the bearing friction losses resulting from the bearing of the pump or motor shaft. Both quantities νᵢ and νₛ can be determined at the factory by measuring the centrifugal pump and are therefore known. Furthermore, the term

$$I \frac{d Q}{d t}$$

describes the moment of inertia of the medium in the impeller. Due to the comparatively small amount of pumped medium in the impeller, the term is comparatively small and can be neglected.

$$I \frac{d Q}{d t}$$

is comparatively small and can be neglected.

The model parameters aₜ, bₜ and cₜ describe the physical relationship between the torque T, flow Q and speed win other words the torque map T(ω, Q) of the centrifugal pump 3 formed from the individual torque curves Tω (Q), whereby the speedω is constant along a torque curve Tω (Q). Since, as previously stated, each pump is measured by the manufacturer and its hydraulic and hydromechanical pump characteristics are known to the manufacturer, the model parameters aₜ, bₜ and cₜ are also known per se. In the present example, the model parameter cₜ is a value that can change with time. Its initial value can also be determined at the factory by measuring the centrifugal pump 3.

The calculated model quantity T_{mdl} is also output at the output of the first function block 9.1 and transferred to the third function block 9.3, in which it is used to calculate the model speed ω_{mdl} by means of the second partial equation G12b of the second integral equation. For the evaluation of this partial equation G12b, the moment of inertia J, the motor torque Tₘₒₜ and the value of a disturbance torque T_{D} are also required that exists in the event of a deviation of the model speed from the actual speed, i.e. is greater than zero in terms of amount. The moment of inertia J of the rotating components (shaft, rotor, impeller) of the centrifugal pump 3 can also be determined at the factory by measuring the centrifugal pump 3 or calculated from design data. The motor torque Tₘₒₜ is fed to the pump-motor model 9 or the third function block 9.3 by the motor control 7. Furthermore, the disturbance torque T_{D} is determined by a disturbance controller 10 and is also fed to the pump-motor model 9 or the third function block 9.3.

Partial equation G12b can thus be evaluated and the model speed ω_{mdl} determined. It thus represents the output signal of the third function block 9.3 as well as the third output variable of the pump-motor model 9.

The equations of the pump-motor model 9 are continuously calculated repeatedly, in particular depending on the clock rate of the processor of the control electronics 4 on which this calculation is performed. In this process, a new flow rate value Q_{mdl} (k+1) or speed value ω_{mdl} (k+1) is calculated in each clock cycle from the flow rate value Q_{mdl} or speed valueω_{mdl} used in the previous clock cycle.

With the aid of the pump-motor model 9 (observer) the actual speed of the centrifugal pump 3 is estimated as the model speedω_{mdl} and fed to a disturbance controller 10 that also receives the actual speedωᵣₑₐₗ of the centrifugal pump 3. The disturbance controller 10 forms a fourth process section IV, compare FIG. 2. The disturbance controller 10 forms a fourth process section IV, compare FIG. 2. It first determines whether and to what extent there is a deviation of the model speed ω_{mdl} from the actual speedωᵣₑₐₗ and determines a disturbance signal T_{D}from this deviation. In this respect, the disturbance controller 10 forms a disturbance signal calculation unit. It is responsible for setting or controlling the model speedω_{mdl} so that it corresponds to the actual speed ωᵣₑₐₗ.

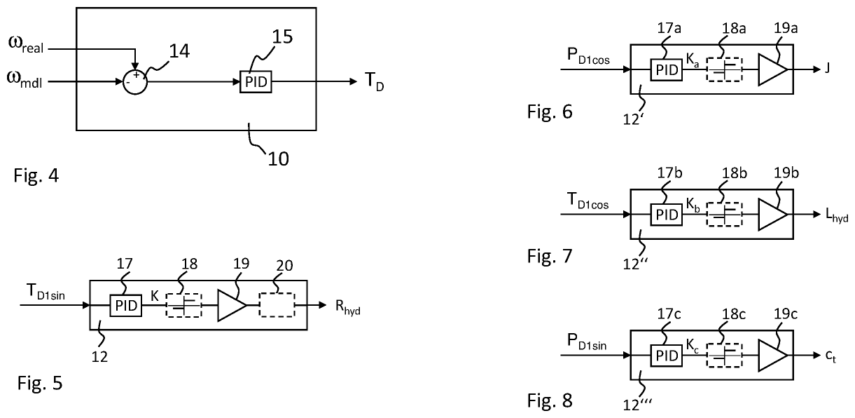

A first embodiment of the disturbance controller 10 is shown in FIG. 4. It comprises a subtractor 14 which calculates the deviation (ωᵣₑₐₗ−ω_{mdl}) of the model speedω_{mdl} from the actual speedωᵣₑₐₗ of the centrifugal pump 3, 4. This part of the disturbance controller 10, together with the pump-motor model 9, can be understood as a “torque observer,” because a deviation of the model speedω_{mdl} from the actual speedωᵣₑₐₗ means a deviation of the model 9 from reality, which manifests itself in a disturbance torque that in turn is responsible for the speed deviation. Furthermore, the disturbance controller 10 comprises a controller 15 having an integral component that is here a PID controller. The calculated deviation or speed difference is fed to this controller 15 and integrated based on the integral component. The physical quantity of the controller output is defined by the connected manipulated variable, so that the controller output signal (manipulated variable of the controller) physically corresponds to a torque.

In the first embodiment of the disturbance controller 10, the controller output signal directly forms the disturbance signal T_{D} that can accordingly be regarded as the disturbance torque T_{D}. If the speedsω_{mdl}, ωᵣₑₐₗ, differ, then the pump-motor model 9 does not match reality. Thus, the disturbance controller 10 may also be referred to as a “disturbance observer,” The disturbance torque T_{D} accelerates the model speed ω_{mdl} when it is less than the actual speed ωᵣₑₐₗ, and brakes the model speed ω_{mdl} when it is greater than the actual speed ωᵣₑₐₗ. In this way, the disturbance signal T_{D} compensates for a deviation of the pump-motor model 9 from reality. Such a deviation can, for example, be caused by inaccurate parameter values, but can also be due to external disturbances, such as torque fluctuations due to particles or bubbles in the pumped medium or due to changing bearing friction.

The PID controller 15 of the disturbance controller 10 is initialized with the value 0. If the speedsωᵣₑₐₗ and ω_{mdl} are identical, their deviation is zero and the disturbance signal T_{D}(disturbance torque) is constant or also zero at the beginning of the process. If there is a negative deviation between the speeds ω_{mdl} and ωᵣₑₐₗ i.e. that the actual speedωᵣₑₐₗ lags behind the model speed ω_{mdl}, the disturbance signal T_{D} falls. This can be interpreted to mean that in reality a disturbance torque (braking torque) is acting, as a result of which the centrifugal pump 3 actually has a lower speed ωᵣₑₐₗ than it is estimated by the pump-motor model 9. In other words, losses (e.g. friction losses/bearing wear, higher hydraulic resistance, higher inertia force, etc.) act in reality.) that are not taken into account in the (idealized) pump-motor model 9, so that the pump-motor model 9 overestimates the model speed ω_{mdl}. If there is a positive deviation between the speeds ω_{mdl} and ωᵣₑₐₗ, i.e. that the model speedω_{mdl} is estimated to be lower than the actual speed ωᵣₑₐₗ, the disturbance signal T_{D} increases steadily as a result of the I component of the controller 15. A too low model speed ω_{mdl} can be present if the pump-motor model 9 models the centrifugal pump 3, 4 together with the connected system 1 too lossy, if necessary overadjusted.

The disturbance signal T_{D} is then fed to an evaluation unit 11 and evaluated therein, which represents a fifth process section V. The evaluation unit 11 according to FIG. 2 is set up to determine a correction signal T_{D1 sin} from the interference signal T_{D}. This is done in such a way that the interference signal T_{D} is first multiplied by a sinusoidal signal whose frequency corresponds to the multiple of the excitation frequency ω_{A}, i.e. the fundamental frequency of the excitation signal fA(t). The product thus formed is then integrated over at least one period T of the excitation signal f_{A} to obtain the correction signal T_{D1 sin}. Mathematically, this is a sinusoidal transformation. The correction signal T_{D1 sin} can thus be determined as follows:

$${T}_{D 1 s i n} = \frac{1}{T} {\int }_{t}^{t + T} {T}_{D} ( t ) \cdot sin ( {ω}_{A} t ) d t$$

The correction signal T_{D1 sin} is then fed to a parameter controller 12 that is set up to carry out an adjustment of a model parameter as a function of the correction signal T_{D1 sin}. In the embodiment according to FIG. 2, the model parameter to be adjusted is (only) the hydraulic resistance R_{hyd} of the pipe network 2.

A first embodiment of the parameter controller 12 is shown in FIG. 5. It comprises a controller 17 with integral component to which the correction signal T_{D1 sin} is fed. The controller 17 is implemented here as a PID controller. The output signal of this controller 17 represents a correction factor K. The controller 17 is initialized with the value 1 as one of the first steps of the method, so that the correction factor K initially has the value 1. The parameter controller 12 further comprises a multiplier 19 which multiplies the correction factor K by an initial value of the model parameter R_{hyd}. Consequently, if the correction factor K=1, the initial value is not corrected so that the model parameter R_{hyd} is equal to the initial value. If the correction signal T_{D1 sin} is zero, the correction factor K remains unchanged. If the correction signal T_{D1 sin} is greater than zero, the correction factor K is increased as a result of the integral component of the controller 17. If the correction signal T_{D1 sin} is less than zero, the correction factor K is decreased as a result of the integration of the correction signal T_{D1 sin}. The model parameter R_{hyd} is consequently dynamically adapted, in particular “controlled with feedback,” by the parameter controller 12, the correction factor K indicating as a manipulated variable the extent of the deviation of the model parameter R_{hyd} from the initial value.

The correction factor K thus generally makes it possible to obtain further information about the centrifugal pump 3, 4 or the pipeline network 2, such as information about ageing/wear of the centrifugal pump 3, deposits on the impeller (clogging) or a fault in the pipeline network. This makes it possible to monitor the condition of the centrifugal pump 3, 4. If the correction factor K exceeds or falls below a predetermined limit value, an error message, a warning and/or maintenance notice can be issued.

The parameter controller 12 may further comprise a correction factor limitation 18 which limits the correction factor K to an upper and/or lower limit value, for example to the upper value 5 or to the lower value ⅕, so that the permissible range of values for the model parameter to be adjusted is at most five times and one fifth of the initial value. The correction factor limiter 18 is thus located signal-wise between the controller 17 and the multiplier 19. The correction factor limiter 18 prevents the model 9 from moving too far away from the real system, for example, due to temporarily incorrect measured values. If, for example, the flow rate Q=0, the resistance R_{hyd}would have to be infinitely large. This means that this condition would never be reached by integration. Conversely, it would then also take a very long time to return from infinity to another operating point. However, since the result does not change significantly at very low volume flows, it makes sense to limit the resistance R_{hyd}. It can also be assumed for other model parameters that they can only change within a certain range. Otherwise, there may be another error, e.g. a measurement error.

Further, the parameter controller 12 may include a linearization unit 20 such that the parameter controller 12 exhibits the same behavior for increase as for decrease and the disturbance signal TD1 sin becomes proportional to the change in flow rate.

The model parameter R_{hyd}, adjusted if necessary by the parameter controller 12, is then fed to the pump-motor model 9. The pump-motor model 9 then uses the adjusted model parameter in the second function block 9.2 to calculate the delivery flow Q_{mdl}.

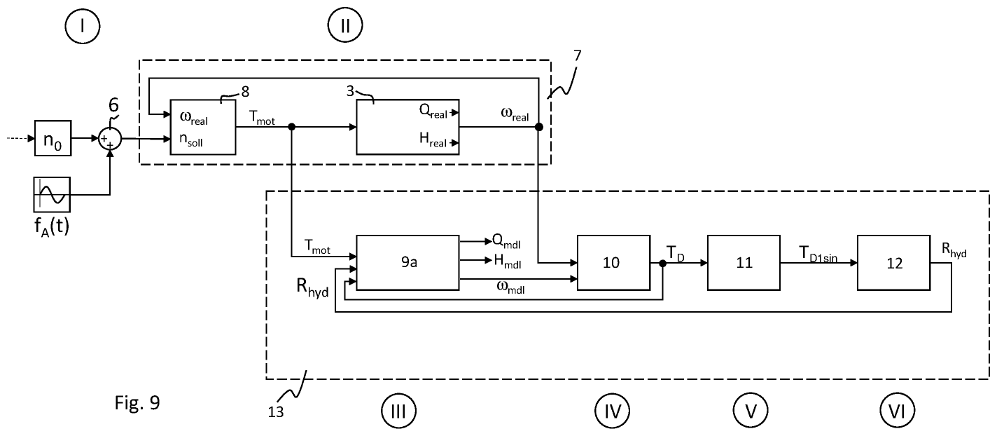

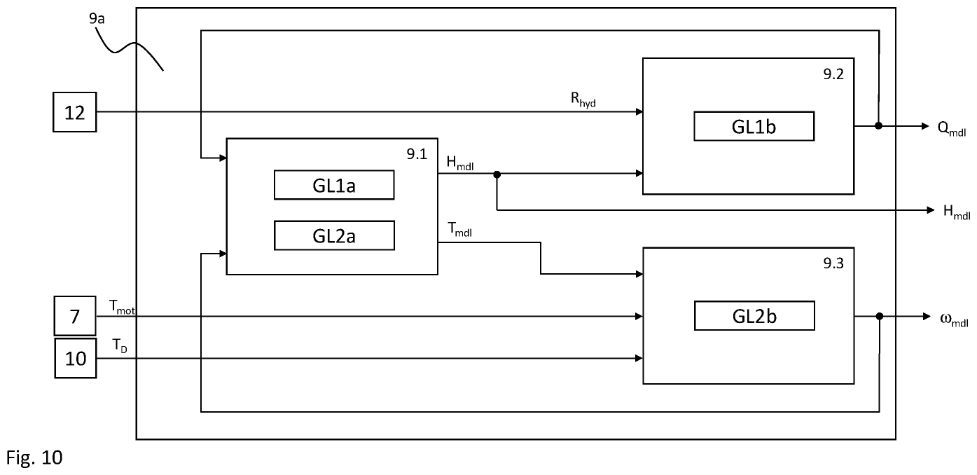

FIGS. 9 and 10 show a second embodiment of the pump-motor model 9a. It differs from the first embodiment in that no actual speed ωᵣₑₐₗ is fed to the pump-motor model 9a from the motor control 7. Instead, the model speed ω_{mdl} calculated internally in the previous cycle is used in the pump-motor model 9a for the individual equations G11a, G12a, for which the output of the third function block 9.3 is fed back to the input of the first function block 9.1, see FIG. 10. This is possible because the disturbance controller 10 is able to compensate very well for any speed error.

The individual sections I-VI of the method according to the invention, which can also be regarded as functions, are summarized once again in the following table:

| Procedure | | |
|---|---|---|
| sec. | Function block | Function |
| I | Speed | Periodic excitation of a reference |
| | specification | speed |
| II | Motor control | Speed control and determining actual |
| | | speed and torque |
| III | Pump-motor | Calculation/observation of speed, head |
| | model | and flow rate |
| IV | Fault | Calculating a disturbance signal; |
| | controller | controller with high bandwidth, or a |
| | | bandwidth of at least one decade above |
| | | the excitation frequency; ensures that |
| | | model speed corresponds to actual speed |
| V | Evaluation | Calculating one or more correction |
| | unit | signals from the disturbance signal |
| VI | Parameter | Model parameter adjustment as a |
| | controller | function of the correction signal |

This method improves the accuracy of the flow rate and/or head determination, since any disturbance torque T_{D} is counteracted by the disturbance controller 10 and the subsequent parameter adjustment in the parameter controller 12, thereby reducing the noise in the flow rate and/or head signal compared to the prior art approach. Thus, the signal quality can be improved or a lower excitation amplitude than in the prior art can be used for the excitation signal while maintaining the quality, or a subsequent smoothing by filtering can be reduced, so that a faster reaction of the centrifugal pump 3, 4 to system state changes or disturbances in the hydraulic pipeline network 2 can take place. As a result of the adjustment of the model parameter during operation of the pump 3, 4, any inaccuracies in the pump-motor model 9 are also compensated for, which may be due to a scattering of the model parameters in series production and/or wear due to ageing, for example of the bearings of the centrifugal pump 3.

In principle, only the hydraulic resistance R_{hyd} needs to be tracked to determine the flow rate Q, at least if the other model parameters are known from a measurement, estimate, calculation, etc., since R_{hyd} is the only dynamically variable parameter. Nevertheless, the hydraulic resistance R_{hyd} could also be determined in another way and fed to the pump-motor model 9. The method according to the invention is thus not limited to tracking the hydraulic resistance R_{hyd} with the evaluation unit 11 and the parameter controller 12. Rather, a single other parameter can also be tracked, such as the moment of inertia J, the hydraulic impedance L_{hyd} or the parameter cₜ. In the case of the moment of inertia J, the parameter controller 12 in FIG. 2 or 9 is formed by the moment of inertia controller 12′ from FIG. 6, in the case of the hydraulic impedance L_{hyd} by the impedance controller 12″ from FIG. 7 and in the case of the parameter cₜ by the cₜ controller 12″′ from FIG. 8. In each of these three cases, the evaluation unit 11 also outputs a different correction signal, as will be explained below.

However, to improve the accuracy of the flow rate determination, in particular also in case of series dispersion (model parameters for different pumps of the same series may differ due to manufacturing and tolerances) as well as over the several years of operation of the centrifugal pump 3, 4, i.e. in case of ageing effects, the above-described further parameters of the pump-motor model 9 can be tracked in addition to the hydraulic resistance. It is then also possible to obtain further information about, for example, the wear of the pump 3, 4.

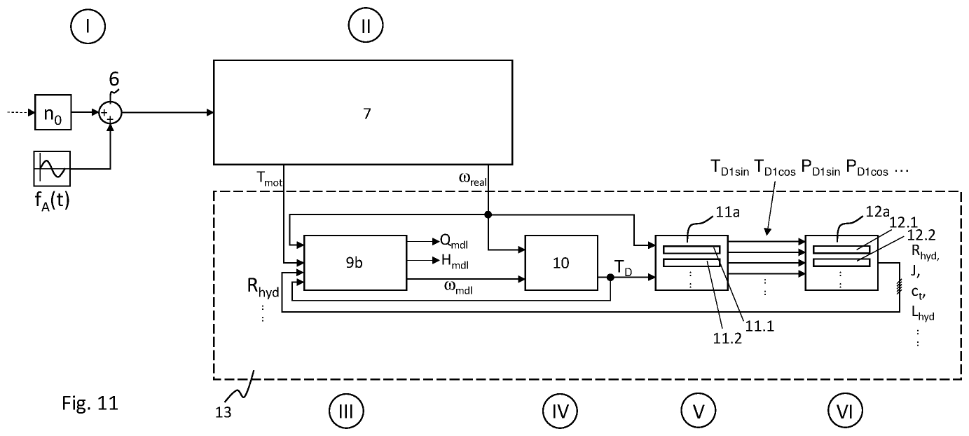

FIG. 11 shows a third variant of the method according to the invention. It differs from the first and second variants essentially in that the evaluation unit 11a receives the actual speedωᵣₑₐₗ and calculates several correction signals, whereby each correction signal can be used to adjust a single model parameter, so that a number of model parameters of the pump-motor model 9b corresponding to the number of correction signals can be adjusted simultaneously. In this regard, each correction signal is calculated in a correction signal calculation unit 11.1, 11.2, all of which are part of the evaluation unit 11a. From the actual speed ωᵣₑₐₗ, the evaluation unit 11a can calculate a second disturbance signal P_{D}. Further, the evaluation unit 11a may calculate one or more correction signals from both the first disturbance signal T_{D} and this second disturbance signal P_{D} respectively.

The evaluation unit 11a according to FIG. 11 is set up to perform a discrete sine/cosine transformation of the disturbance signal T_{D} or disturbance torque T_{D} at the fundamental frequencyω_{A} of the excitation signal f_{A}(t). On the one hand, by integrating the product of the disturbance signal T_{D} and a sinusoidal signal with the this fundamental frequencyω_{A}, a first correction signal T_{D1 sin} which represents an active component (or real component) and is in phase with the excitation signal f_{A} (t), and a second correction signal T_{D1 cos} which represents a blind part (or imaginary part) and is orthogonal to the excitation signal f_{A} (t). In addition, the DC component T_{D0} of the disturbance signal T_{D} can be calculated as a third correction signal. These three correction signals can be used to adapt three parameters of the pump-motor model 9b, since they would disappear in a non-faulty model. Mathematically, the three correction signals can be T_{D1 sin}, T_{D1 cos}, T_{D0} can be represented by the following integrals, each of which is calculated in one of the correction signal calculation units 11.1, 11.2:

$${T}_{D 1 s i n} = \frac{1}{T} {\int }_{t}^{t + T} {T}_{D} ( t ) \cdot sin ( {ω}_{A} t ) dt \\ {T}_{D 1 c o s} = \frac{1}{T} {\int }_{t}^{t + T} {T}_{D} ( t ) \cdot cos ( {ω}_{A} t ) dt \\ {T}_{D 0} = \frac{1}{T} {\int }_{t}^{t + T} {T}_{D} ( t ) d t$$

In the same way even further frequencies can be excited and evaluated. One receives thereby per frequency nω_{A}t two further correction signals T_{Dn sin}, T_{Dn cos} from the first interference signal T_{D} that can be calculated in corresponding correction signal calculation units 11.1, 11.2:

$${T}_{D n s i n} = \frac{1}{T} {\int }_{t}^{t + T} {T}_{D} ( t ) \cdot sin ( n {ω}_{A} t ) dt \\ {T}_{D n c o s} = \frac{1}{T} {\int }_{t}^{t + T} {T}_{D} ( t ) \cdot cos ( n {ω}_{A} t ) d t$$

These can be used to track two other model parameters.

As already mentioned, the evaluation unit 11a is further set up to calculate a second disturbance signal P_{D} and to perform a discrete sine/cosine transformation of this second disturbance signal P_{D} at the fundamental frequency of the excitation signal f_{A} (t). For this purpose, the product of the first disturbance signal or the disturbance torque T_{D} and the actual speed ωᵣₑₐₗ is first calculated that represents a power P_{D}=T_{D}·ωᵣₑₐₗ which can be referred to as “disturbance power” in analogy to the disturbance torque T_{D}.

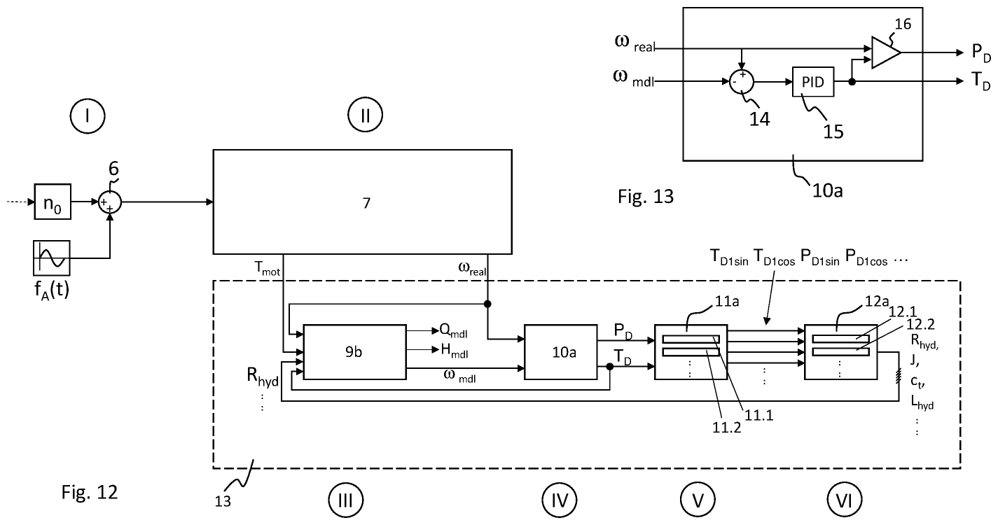

Alternatively to the calculation of the second disturbance signal P_{D} in the evaluation unit 11a, this calculation can be performed in the disturbance controller 10a. FIGS. 12 and 13 illustrate such an embodiment variant. Thus, the actual speed does not have to be supplied to the evaluation unit. As can be seen from FIG. 13, the disturbance controller 10a used in FIG. 12 in this case additionally comprises a multiplier 16 which multiplies the output signal of the controller 15, i.e. the disturbance torque T_{D}, by the actual speed ωᵣₑₐₗ and thus provides a disturbance power P_{D} at its output. The disturbance torque T_{D}is then the first disturbance signal T_{D} and the disturbance power P_{D} is the second disturbance signal P_{D}, both of which are transferred by the disturbance controller 10a to the evaluation unit 11a so that it does not have to calculate the second disturbance signal P_{D}.

From the second disturbance signal P_{D}, the evaluation unit 11a calculates, by integrating the product of the second disturbance signal P_{D} and a sinusoidal signal having this fundamental frequencyω_{A}, a fourth correction signal P_{D1 sin} which represents an active part (or real part) and is in phase with the excitation signal f_{A} (t), and a fifth correction signal P_{D1 cos} representing a blind part (or imaginary part) and being orthogonal to the excitation signal f_{A} (t). In addition, the DC component P_{D0} of the second disturbance signal P_{D} can be calculated as the sixth correction signal. Thus, three further correction signals P_{D1 sin}, P_{D1 cos}, P_{D0} can be determined by forming the following integrals, which is performed in each case in one of the correction signal calculation units 11.1, 11.2:

$${P}_{D 1 s i n} = \frac{1}{T} {\int }_{t}^{t + T} {P}_{D} ( t ) \cdot sin ( ω t ) dt \\ {P}_{D 1 c o s} = \frac{1}{T} {\int }_{t}^{t + T} {P}_{D} ( t ) \cdot cos ( ω t ) dt \\ {P}_{D 0} = \frac{1}{T} {\int }_{t}^{t + T} {P}_{D} ( t ) d t$$

with P_{D}=T_{D}(t)·ωᵣₑₐₗ(t)

In the same way, further frequencies can be excited and evaluated. One receives thereby per frequency nω_{A}t two further correction signals P_{Dn sin}, P_{Dn cos} from the second interference signal P_{D}

$${P}_{D n s i n} = \frac{1}{T} {\int }_{t}^{t + T} {P}_{D} ( t ) \cdot sin ( n {ω}_{A} t ) dt \\ {P}_{D n c o s} = \frac{1}{T} {\int }_{t}^{t + T} {P}_{D} ( t ) \cdot cos ( n {ω}_{A} t ) d t$$

which can be used to track two additional model parameters.

Of course, the evaluation unit 11a does not necessarily have to calculate all the above-described correction signals. Rather, this can be done as required and desired.

The correction signals T_{D1 sin}, T_{D1 cos}, P_{D1 sin}, P_{D1 cos}, T, P_{D0D0} etc. calculated by the evaluation unit 11 are then fed to the parameter controller 12a that is set up to adjust one model parameter per correction signal. This is done in single parameter controllers 12.1, 12.2, etc., each of which is supplied with a particular correction signal. Thus, six model parameters can be adjusted simultaneously by this parameter controller 12a. The parameter controller 12 thus consists, more precisely, of a number of individual parameter controllers 12.1, 12.2, each of which may have a structure as in FIG. 5, 6, 7 or 8, and each of which specifies a model parameter. In FIG. 5 this is the hydraulic resistance R_{hyd}, in FIG. 6 the inertia J of the rotating components of the centrifugal pump 3, in FIG. 7 the hydraulic impedance L_{hyd} and in FIG. 8 the model parameter cₜ. The parameter controller 12 in FIG. 5 differs from the other parameter controllers 12′, 12″, 12″′ of FIGS. 6 to 8 only in that it has a linearisation unit 20. In addition, each parameter controller 12, 12′, 12″, 12″′ has a controller 17, 17a, 17b, 17c with an integral component which, for example, can be as a PID controller, a multiplier 19, 19′, 19″, 19″′ for multiplying the respective correction factor K, Kₐ, K_{b}, K_{c} by the corresponding initial value of the respective model parameter R_{hyd}, J, L_{hyd}, cₜ, and optionally a correction factor limiter 18, 18′, 18″, 18′″. The operation of each parameter controller 12, 12′, 12″, 12′″ is as previously described with respect to the first embodiment.

In principle, each individual correction signal can be used for the tracking of a model parameter. However, it should be noted that signals which represent an active component, i.e. signals which are in phase with the excitation of the pump speed—i.e. the sinusoidal signals in the case of sinusoidal excitation—adjust those model parameters which predominantly act on the active power. This is the case with the hydraulic resistance R_{hyd} and the model parameter cₜ, which is why the parameter controllers 12, 12″ are fed the correction signals T_{D1 sin} and P_{D1 sin} for these model parameters in FIGS. 5 and 8. However, it does not matter which of these parameter controllers 12, 12″′ receives the correction signal T_{D1 sin} and which receives the correction signal P_{D1 sin}. The correction signal supply can be interchanged to this extent.

In contrast, those correction signals which represent reactive power, i.e. are 90° out of phase with the excitation of the pump speed, i.e. the previously mentioned correction signals T_{D1 cos} and P_{D1 cos}, should adapt such model parameters which predominantly influence the reactive power. This is the case with the inertia J and the hydraulic impedance L_{hyd}, which is why the parameter controllers 12′, 12″ are supplied with the correction signals T_{D1 cos} and P_{D1 cos} for these model parameters in FIGS. 6 and 7. Again, it does not matter which of these parameter controllers 12′, 12″ receives the correction signal T_{D1 cos} and which receives the correction signal P_{D1 cos}. The correction signal supply can also be interchanged in this respect.

Experiments have shown that the following assignment of the correction signals T_{D1 sin}, T_{D1 cos}, P_{D1 sin}, P_{D1 cos}, T_{D0}, P_{D0} to the model parameters is advantageous:
T_{D1 sin} to adjust the model parameter R_{hyd}
T_{D1 cos} to adjust the model parameter L_{hyd}
P_{D1 sin} to adjust the model parameter cₜ
P_{D1 cos} to fit the model parameter J
T_{D0} to adjust the model parameter νₛ
P_{D0} to adjust the model parameter νᵢ

However, other combinations are also possible. According to this assignment, the individual correction signals can be fed to that single parameter controller 12.1, 12.2, etc. which adjusts the correspondingly assigned model parameter.

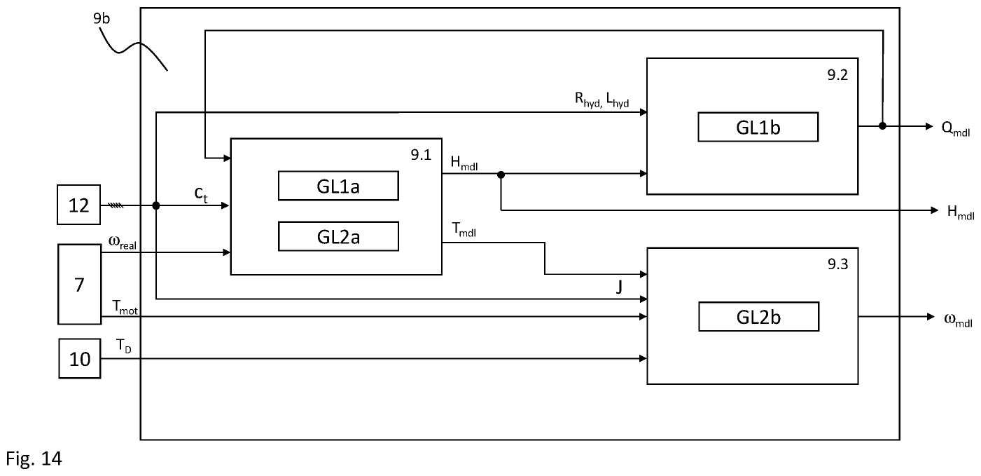

The output signals of the single parameter controllers 12.1, 12.2, etc., i.e. the adjusted model parameters, are then made available to the pump-motor model 9b, whose signal flow diagram FIG. 14 shows. The pump-motor model 9b can then use these new values of the model parameters to calculate the model speedω_{mod}, the flow rate Q_{mdl} and the head H_{mdl}. For this purpose, the model parameter cₜ is fed to the first function block 9.1, the two model parameters R_{hyd} and L_{hyd} are fed to the second function block 9.2 and the model parameter J is fed to the third function block 9.3, within each of which the new model parameter values are then used in the corresponding partial equations G11b, G12a, G12b.

It should be noted that the above description is given by way of example only for purposes of illustration and in no way limits the scope of protection of the invention. Features of the invention indicated as “may,” “exemplary,” “preferred,” “optional,” “ideal,” “advantageous,” “optionally,” “suitable” or the like are to be regarded as purely optional and likewise do not limit the scope of protection that is defined exclusively by the claims. To the extent that the above description recites elements, components, process steps, values or information having known, obvious or foreseeable equivalents, such equivalents are embraced by the invention. Likewise, the invention includes any changes, variations or modifications to embodiments that involve the substitution, addition, alteration or omission of elements, components, process steps, values or information, so long as the basic idea of the invention is maintained, regardless of whether the change, variation or modification results in an improvement or deterioration of an embodiment.

Although the above description of the invention mentions a plurality of physical, non-physical or procedural features in relation to one or more specific example of the invention, these features may also be used in isolation from the specific example of the invention, at least to the extent that they do not require the mandatory presence of further features. Conversely, these features mentioned in relation to one or more specific embodiment may be combined with each other and with further disclosed or non-disclosed features of shown or non-shown embodiments as desired, at least to the extent that the features are not mutually exclusive or do not lead to technical incompatibilities.

1. A method of determining the delivery flow and/or the delivery head of a speed-controlled centrifugal pump, wherein a reference speed or a torque of the centrifugal pump is acted upon by a periodic excitation signal of a specific excitation frequency to achieve a modulated setpoint speed, the method comprising the steps of:
a. determining and adjusting a torque required to achieve the modulated reference speed or adjustment of the modulated torque,
b. determining the actual speed of the centrifugal pump,
c. calculating a model speed with the aid of a mathematical pump-motor model simulating the behavior of the centrifugal pump within a hydraulic system,
d. calculating at least one disturbance signal from a deviation of the model speed from the actual speed of the centrifugal pump,
e. determining at least one correction signal by integrating the product of the disturbance signal and a sine or cosine signal with a multiple of the excitation frequency over at least one period of the excitation signal,
f. adapting at least one model parameter of the pump-motor model as a function of the correction signal, and
g. calculating the flow rate and/or the head using the adapted pump-motor model.

2. The method according to claim 1, wherein the pump-motor model comprises at least a first equation in integral form for calculating the flow rate and a second equation in integral form for calculating the model speed, and these two equations are repeatedly cyclically evaluated.

3. The method of claim 2, wherein the first equation is used in the following integral form:
$${Q}_{m d l} = \frac{1}{{L}_{h y d}} {\int }_{0}^{t} ( ( a {ω}^{2} - b {Q}_{m d l} ω - c {Q}_{m d l}^{2} ) - {R}_{h y d} {Q}_{m d l}^{2} - {H}_{s t a t i c} ) dt \\ or \qquad G 11$$
$${Q}_{m d l} ( k + 1 ) = {Q}_{m d l} ( k ) + \frac{1}{{L}_{h y d}} ( ( a {ω}^{2} ( k ) - b {Q}_{m d l} ( k ) ω ( k ) - c {Q}_{m d l}^{2} ( k ) ) - {R}_{h y d} {Q}_{m d l}^{2} ( k ) - {H}_{s t a t i c} ( k ) ) \cdot Δ t \qquad G 11$$
where
Q_{mdl} the flow rate of the centrifugal pump,
ω a speed or rotational frequency of the centrifugal pump (ω=2πn),
a, b, care parameters that describe the hydraulic pump map (H(Q, ω)) by means of pump curves,
R_{hyd} the hydraulic resistance of the hydraulic system,
L_{hyd} the hydraulic inductance of the hydraulic system Hstatic is a geodetic head,
k is a discrete time and
Δt is the time interval between one time k and the next time k+1.

4. The method according to claim 2 wherein the first equation (G11) is used in the form of the following two partial equations (G11a, G11b) which are calculated repeatedly one after the other:
$${H}_{m d l} = a {ω}^{2} - b {Q}_{m d l} ω - c {Q}_{m d l}^{2} \qquad G 11 a$$
$${Q}_{m d l} = \frac{1}{{L}_{h y d}} {\int }_{0}^{t} ( {H}_{m d l} - {R}_{h y d} {Q}_{m d l}^{2} - {H}_{s t a t i c} ) dt \\ or \qquad G 11 b$$
$${H}_{m d l} ( k ) = a {ω}^{2} ( k ) - b {Q}_{m d l} ( k ) ω ( k ) - c {Q}_{m d l}^{2} ( k ) \qquad G 11 a$$
$${Q}_{m d l} ( k + 1 ) = {Q}_{m d l} ( k ) + \frac{1}{{L}_{h y d}} ( {H}_{m d l} ( k ) - {R}_{h y d} {Q}_{m d l}^{2} ( k ) - {H}_{static} ( k ) ) \cdot Δ t \qquad G 11 b$$
where
H_{mdl} is the delivery head of the centrifugal pump.
Q_{mdl} the flow rate of the centrifugal pump,
ω a speed or rotational frequency of the centrifugal pump (ω=2πn),
a, b, care parameters that describe the hydraulic pump map (H(Q, ω)) by means of pump curves,
R_{hyd} the hydraulic resistance of the hydraulic system,
L_{hyd} the hydraulic inductance of the hydraulic system,
Hstatic a geodetic head
k is a discrete time and
Δt is the time interval between one time k and the next time k+1.

5. The method according to claim 2, wherein the second equation is used in the following integral form:
$${ω}_{mdl} = \frac{1}{J} {\int }_{0}^{t} ( {T}_{m o t} - ( {a}_{t} {Q}_{m d l} ω - {b}_{t} {Q}_{m d l}^{2} - {c}_{t} \frac{{Q}_{m d l}^{3}}{ω} + {v}_{i} {ω}^{2} + {v}_{s} ω - I \frac{d Q}{d t} ) + {T}_{D} ) dt or \qquad G 12$$
$${ω}_{m d l} ( k + 1 ) = {ω}_{m d l} ( k ) + \frac{1}{J} ( {T}_{m o t} ( k ) - ( {a}_{t} {Q}_{m d l} ( k ) ω ( k ) - {b}_{t} {Q}_{m d l}^{2} ( k ) - {c}_{t} \frac{{Q}_{m d l}^{3} ( k )}{ω ( k )} + {v}_{i} {ω}^{2} ( k ) + {v}_{s} ω ( k ) - I \frac{Q ( k ) - Q ( k - 1 )}{Δ t} ) + {T}_{D} ( k ) ) \cdot Δ t \qquad G 12$$
where
Tₘₒₜ the mechanical torque of the motor (motor torque) of the centrifugal pump,
T_{D} the calculated disturbance signal in the form of a moment (disturbance moment),
Q_{mdl} the flow rate of the centrifugal pump,
ω_{mdl} the model speed or rotational frequency of the centrifugal pump (ω=2πn),
ω a speed or rotational frequency of the centrifugal pump (ω=2πn),
aₜ, bₜ, cₜ are parameters describing the static torque map (T(Q, ω)) of the pump by means of torque curves,
νᵢ a quantity describing the friction between impeller and medium
νₛ a quantity describing the friction in the bearing
J the mass inertia of the rotating components of the centrifugal pump (impeller, shaft, rotor),
The mass inertia of the pumped medium in the impeller,
k is a discrete time and
Δt is the time interval between one time k and the next time k+1.

6. The method according to claim 2 wherein the second equation is used in the form of the following two partial equations (G12a, G12b) which are calculated successively, cyclically repeated:
$${T}_{m d l} = {a}_{t} {Q}_{m d l} ω - {b}_{t} {Q}_{m d l}^{2} - {c}_{t} \frac{{Q}_{m d l}^{3}}{ω} + {v}_{i} {ω}^{2} + {v}_{s} ω - I \frac{d Q}{d t} \qquad G 12 a$$
$${ω}_{m d l} = \frac{1}{J} {\int }_{0}^{t} ( {T}_{m o t} - {T}_{m d l} + {T}_{D} ) dt or \qquad G 12 b$$
$${T}_{m d l} ( k ) = {a}_{t} {Q}_{m d l} ( k ) ω ( k ) - {b}_{t} {Q}_{m d l}^{2} ( k ) - {c}_{t} \frac{{Q}_{m d l}^{3} ( k )}{ω ( k )} + {v}_{i} {ω}^{2} ( k ) + {v}_{s} ω ( k ) - I \frac{Q ( k ) - Q ( k - 1 )}{Δ t} \qquad G 12 a$$
$$b {ω}_{m d l} ( k + 1 ) = {ω}_{m d l} ( k ) + \frac{1}{J} ( {T}_{m o t} ( k ) - {T}_{m d l} ( k ) + {T}_{D} ( k ) ) \cdot Δ t \qquad G 12$$
where
T_{mdl} a pump torque of the centrifugal pump
Tₘₒₜ the mechanical torque of the motor (motor torque) of the centrifugal pump,
T_{D} the calculated disturbance signal in the form of a moment (disturbance moment),
Q_{mdl} the flow rate of the centrifugal pump,
ω_{mdl} the model speed or rotational frequency of the centrifugal pump (ω=2πn) ,
ω a speed or rotational frequency of the centrifugal pump (ω=2πn),
aₜ, bₜ, cₜ are parameters describing the static torque map (T(Q, ω)) of the pump by means of torque curves,
νᵢ a quantity describing the friction between impeller and medium
νₛ a quantity describing the friction in the bearing
J the mass inertia of the rotating components of the centrifugal pump (impeller, shaft, rotor),
Idis the mass inertia of the pumped medium in the impeller,
k is a discrete time and
Δt is the time interval between one time k and the next time k+1.

7. The method according to claim 1, wherein the difference between the model speed and the actual speed is fed to a controller containing at least one integral component, the output signal of this controller forming the disturbance signal or the disturbance signal being formed by multiplying the output signal of this controller by the actual speed.

8. The method according to claim 1, wherein in step d. a first disturbance signal and a second disturbance signal are determined by supplying the difference between the model speed and the actual speed to a controller containing at least one integral component, and the output signal of this controller forms the first disturbance signal and the second disturbance signal is formed by multiplying the output signal of this controller by the actual speed.

9. The method according to claim 1, wherein two or more correction signals are determined from the disturbance signal or from each of the disturbance signals from the disturbance signal or from each of the disturbance signals, and each correction signal is used to adapt in each case a specific model parameter of the pump-motor model.

10. The method according to claim 1, wherein the model parameter is the hydraulic resistance of the system or the parameter, and in step e. the sine or cosine signal is used which is in phase with the excitation signal.

11. The method according to claim 8, wherein the hydraulic resistance is adjusted in dependence of a first correction signal formed from the second disturbance signal and/or that the parameter is adjusted in dependence of a first correction signal formed from the first disturbance signal.

12. The method according to claim 1, wherein the model parameter is the mass inertia of the centrifugal pump or the hydraulic inductance of the system and in step e. that sine or cosine signal is used which is 90° out of phase with the excitation signal.

13. The method at least according to claim 8, wherein the mass inertia of the centrifugal pump is adjusted as a function of a second correction signal formed from the second disturbance signal, and/or in that the hydraulic inductance of the system is adjusted as a function of a second correction signal formed from the first disturbance signal.

14. The method according to claim 1, wherein the adaptation of the model parameter is carried out using a controller containing an integral component, to which the correction signal is supplied, the controller output signal being multiplied by an initial value for the model parameter to obtain the adjusted model parameter.

15. A centrifugal pump having a centrifugal pump, an electric motor driving it and control electronics for controlling with or without feedback the electric motor, wherein the control electronics are set up to carry out the method according to claim 1.
